(19) United States
(12) Patent Application Publication
(10) Pub. No.: US 2025/0112198 A1
(43) Pub. Date: Apr. 3, 2025

(54) IN-CAVITY EPOXY PLACEMENT FOR PACKAGE RELIABILITY

(71) Applicant: Intel Corporation, Santa Clara, CA (US)

(72) Inventors: Pratyasha Mohapatra, Hillsboro, OR (US); Kyle Davidson, Hillsboro, OR (US); Brian Franco, Portland, OR (US)

(73) Assignee: Intel Corporation, Santa Clara, CA (US)

(21) Appl. No.: 18/375,248

(22) Filed: Sep. 29, 2023

(51) Int. Cl. H01L 23/00

(52) U.S. Cl. CPC H01L 24/73; H01L 24/14; H01L 24/16; H01L 24/27; H01L 24/29; H01L 24/30; H01L 24/32; H01L 24/33; H01L 24/81; H01L 24/83; H01L 24/92; H01L 2224/14133; H01L 2224/16227; H01L 2224/27312; H01L 2224/2732; H01L 2224/27334; H01L 2224/2929; H01L 2224/29386; H01L 2224/30164; H01L 2224/32055; H01L 2224/32225; H01L 2224/3303; H01L 2224/33051; H01L 2224/33164; H01L 2224/73203; H01L 2224/81191; H01L 2224/8121; H01L 2224/81815; H01L 2224/831; H01L 2224/83192; H01L 2224/8321; H01L 2224/83862; H01L 2224/9211; H01L 2224/92125; H01L 2924/05442; H01L 2924/0665

(57) ABSTRACT

An apparatus is provided which comprises: a device surface, wherein the device surface comprises an array of solder contacts, a substrate surface, wherein the substrate surface comprises an array of pads, the array of solder contacts coupled with the array of pads, and a formation of epoxy coupled with the device surface and the substrate surface, wherein the formation of epoxy is entirely within an area of the array of solder contacts. Other embodiments are also disclosed and claimed.

### BACKGROUND

Computing platforms, such as desktops, laptops or smart phones, for example, are expected to have increased performance compared with previous iterations. One way that manufacturers of computing platforms can achieve increased performance is by integrating more integrated circuit devices into a single package. With increased integration, there is a corresponding increase in miniaturization of solder joints that experience comparatively higher levels of stress. Conventional solutions to deal with solder joint reliability may be problematic in the presence of higher speed interconnects that are increasingly sensitive to insertion loss issues. For example, capillary underfill is a conventional process of dispensing a liquid material into the void between a semiconductor die and its substrate. The material flows into the void due to capillary action, displacing any air or other gases that may be present. This creates a strong, reliable bond between the die and its substrate, which helps to improve the reliability of the device. Capillary underfill is typically used in high-reliability applications, such as mobile devices, automotive electronics, and medical devices. The capillary underfill material is epoxy resin that is dispensed onto the die and then cured using heat and pressure. The resin flows into the void and cures to form a strong, flexible bond between the die and its substrate. While capillary underfill provides a strong, reliable bond between the die and its substrate, by contacting solder contacts that may communicate high speed signals, the capillary underfill may negatively impact signal quality. Therefore, there is a need for high performance architectures that address solder joint reliability without introducing insertion loss.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of an example in-cavity epoxy placement for package reliability, according to some embodiments,

FIG. 2 illustrates a plan view of an example in-cavity epoxy placement for package reliability, according to some embodiments,

FIGS. 3A-3F illustrate cross-sectional views of example manufacturing steps of forming an example in-cavity epoxy placement for package reliability, according to some embodiments,

FIG. 4 illustrates a cross-sectional view of an example in-cavity epoxy placement for package reliability, according to some embodiments,

FIG. 5 illustrates a flowchart of a method of forming an example in-cavity epoxy placement for package reliability, in accordance with some embodiments, and

FIG. 6 illustrates a smart device or a computer system or a SoC (System-on-Chip) which includes in-cavity epoxy placement for package reliability, according to some embodiments.

### DETAILED DESCRIPTION

In-cavity epoxy placement for package reliability is generally presented. In this regard, embodiments of the present disclosure enable packages with reliable solder joints through the use of selectively placed epoxy in areas of stress without the need for capillary underfill, which may have deleterious effects on high-speed interconnects. One skilled in the art would appreciate that embodiments described herein may enable more complex, higher power, highly integrated devices. Additionally, the architectures described herein may offer improved reliability, and thereby enable enhanced features. Also, by selectively placing epoxy, the total volume and cost of materials used can be much lower and the process can be accomplished much quicker.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

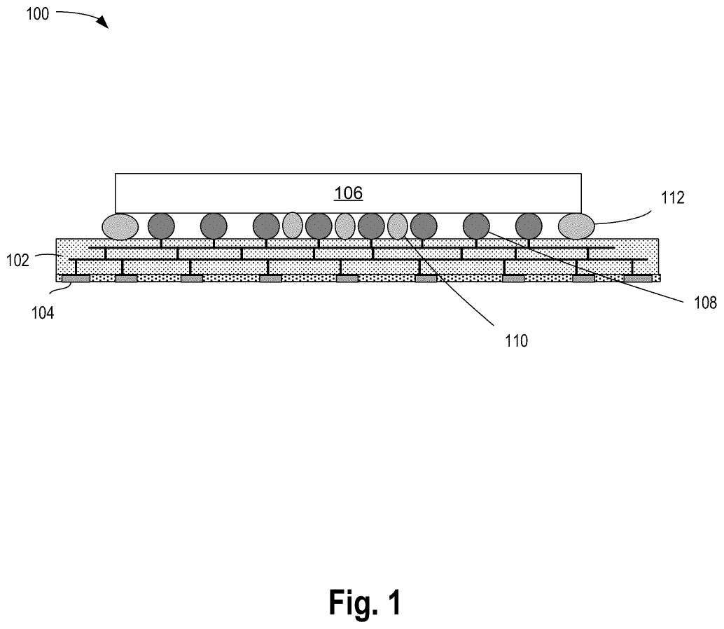

FIG. 1 illustrates a cross-sectional view of an example in-cavity epoxy placement for package reliability, according to some embodiments. As shown, device package 100 includes interconnect layers 102, package contacts 104, integrated circuit device 106, solder contacts 108, in-cavity epoxy 110, and edge epoxy 112. In some embodiments, device package 100 may include additional routing or interconnect layers, core layers, or other components or features, not shown herein.

Interconnect layers 102 may be formed over other layers, for example a core layer (not shown). In some embodiments, interconnect layers 102 may include multiple layers of interlayer dielectric, such as organic dielectric build-up films over an adhesion promoting layer of doped silicon dioxide, for example, along with metal wires to route contacts of package contacts 104 to solder contacts 108 of integrated circuit device 106. In some embodiments, interconnect layers 102 may fan-in a contact pitch from package contacts 104 to solder contacts 108 of integrated circuit device 106. Solder contacts 108 may conductively couple integrated circuit device 106 with interconnect layers 102.

Integrated circuit device 106 may represent any type of integrated circuit device or device package, including for example a ball grid array (BGA) chip that includes an underside with an array of solder contacts 108. In some embodiments, integrated circuit device 106 may be a computing or communications or controller that includes high speed input and output signals that would be particularly sensitive to signal loss that may be introduced by a traditional capillary underfill process due to the high dielectric constant of such underfill material compared to air. In some embodiments, integrated circuit device 106 may be a memory device, such as a high bandwidth memory (HBM). In some embodiments, integrated circuit device 106 may be an intelligent power device (IPD). In other embodiments, integrated circuit device 106 may be a photonic integrated circuit (PIC). While shown as being a single device, integrated circuit device 106 may be implemented as a stack of multiple homogeneous or heterogeneous devices.

In some embodiments, in-cavity epoxy 110 may be a thermal-cured epoxy, though other epoxies may be used. In some embodiments, in-cavity epoxy 110 is a high viscosity adhesive, such as a surface mount adhesive. In some embodiments, in-cavity epoxy 110 may be a commercially available adhesive. In some embodiments, in-cavity epoxy 110 may include filler materials in an epoxy resin. In some embodiments, in-cavity epoxy 110 may include filler, for example silica, at between 30 and 85 percent by volume. In some embodiments, in-cavity epoxy 110 may have a coefficient of thermal expansion (CTE) of less than about 40 ppm/° C.

As used herein, epoxy can refer to a class of thermosetting polymers made from monomers that contain at least two epoxide groups. These resins provide strong adhesion, chemical resistance and other specialized properties. Due to these qualities, epoxy resins are used as surface adhesives and edge bonding of semiconductor devices. Epoxy resins are typically two-component systems, consisting of a resin and a hardener. The resin contains the epoxide groups, while the hardener is a compound that can react with the epoxy groups to form a cross-linked network. This cross-linked network is what gives epoxy resins their strength, durability and chemical resistance. The properties of epoxy resins can be modified by varying the type of resin, hardener and curing conditions. For example, adding fillers to epoxy resins can improve their strength and toughness. Adding curing agents that cure at lower temperatures can make epoxy resins easier to work with.

In some embodiments, in-cavity epoxy 110 may be screen printed, while in other embodiments in-cavity epoxy 110 may be jetted or dispensed by other methods. In some embodiments, in-cavity epoxy 110 may be selectively placed in locations shown through testing to be areas of higher stress for solder contacts 108, which may include cavities or areas with larger spacing between solder contacts 108.

Edge epoxy 112 may be present under one or more edges of integrated circuit device 106. In some embodiments, edge epoxy 112 is a same composition as in-cavity epoxy 110, while in other embodiments, edge epoxy 112 may have a different composition than in-cavity epoxy 110, for example a different percentage of fillers may be present.

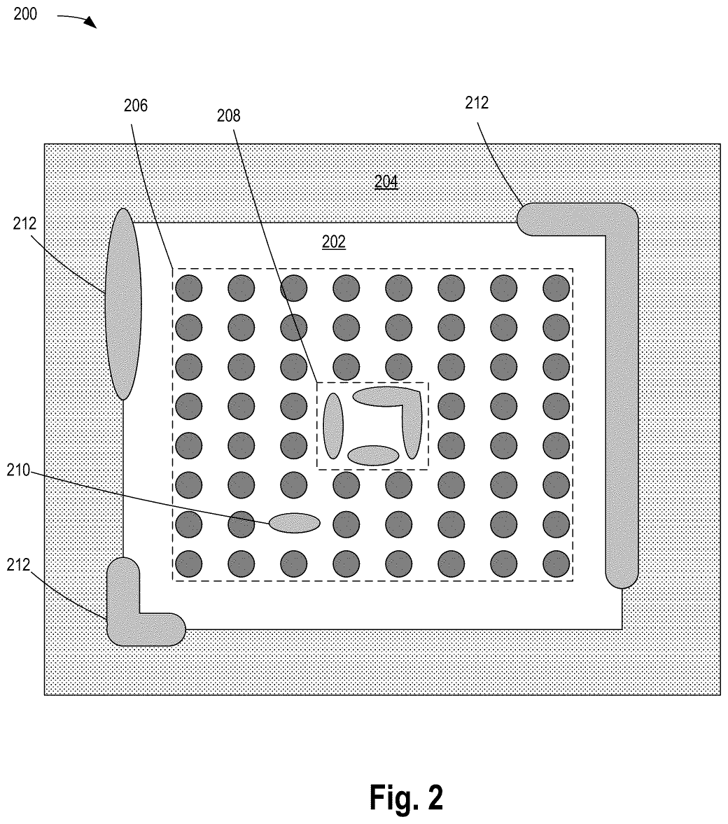

FIG. 2 illustrates a plan view of an example in-cavity epoxy placement for package reliability, according to some embodiments. As shown package 200 may include integrated circuit device 202, package substrate 204, array of solder contacts 206, in-cavity epoxy formation 208, in-cavity epoxy formation 210, and edge epoxy 212. While shown as including two in-cavity epoxy formations 208 and 210, more or fewer in-cavity epoxy formations may be present in any configuration.

As used herein, a cavity may refer to any gaps or spacings between solder contacts within array of solder contacts 206, which may represent BGA contacts. In some embodiments, a cavity could be an absence of solder contacts in a rectangular central portion of array of solder contacts 206. In some embodiments a cavity could be an x by y absence of solder contacts from discernible rows and columns within array of solder contacts 206. In some embodiments, a cavity could be the absence of a single solder contact from within array of solder contacts 206 or even a space or gap between solder contacts within array of solder contacts 206. In some embodiments in-cavity epoxy formations 208 and 210 are selectively placed adjacent solder contacts within array of solder contacts 206 that are determined to be under relatively higher levels of mechanical stress.

While shown as being present along four sides of a rectangular cavity, in-cavity epoxy formation 208 may be present along fewer sides in some embodiments. Also, while shown as including one combined segment along two sides along with two discrete segments, in-cavity epoxy formation 208 may include any combination of discrete and/or combined segments. In some embodiments, in-cavity epoxy formations 208 and 210 may have a width of less than about one or two millimeters.

In some embodiments, edge epoxy 212 may be present between integrated circuit device 202 and package substrate 204 along any or all sides of integrated circuit device 202, in discrete or combined segments.

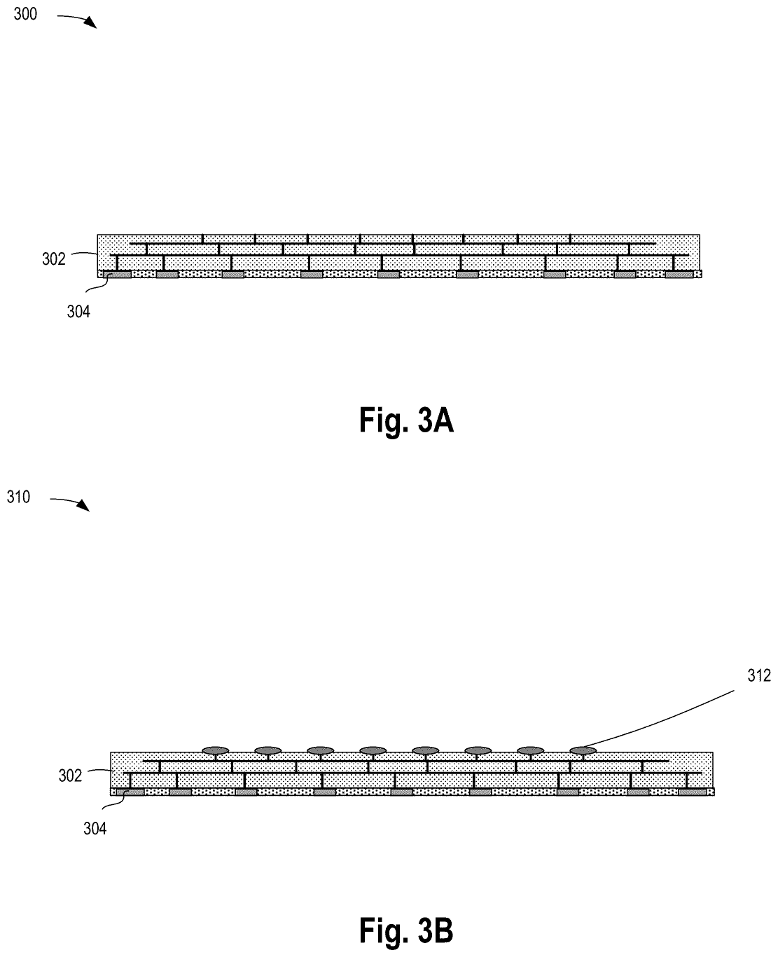

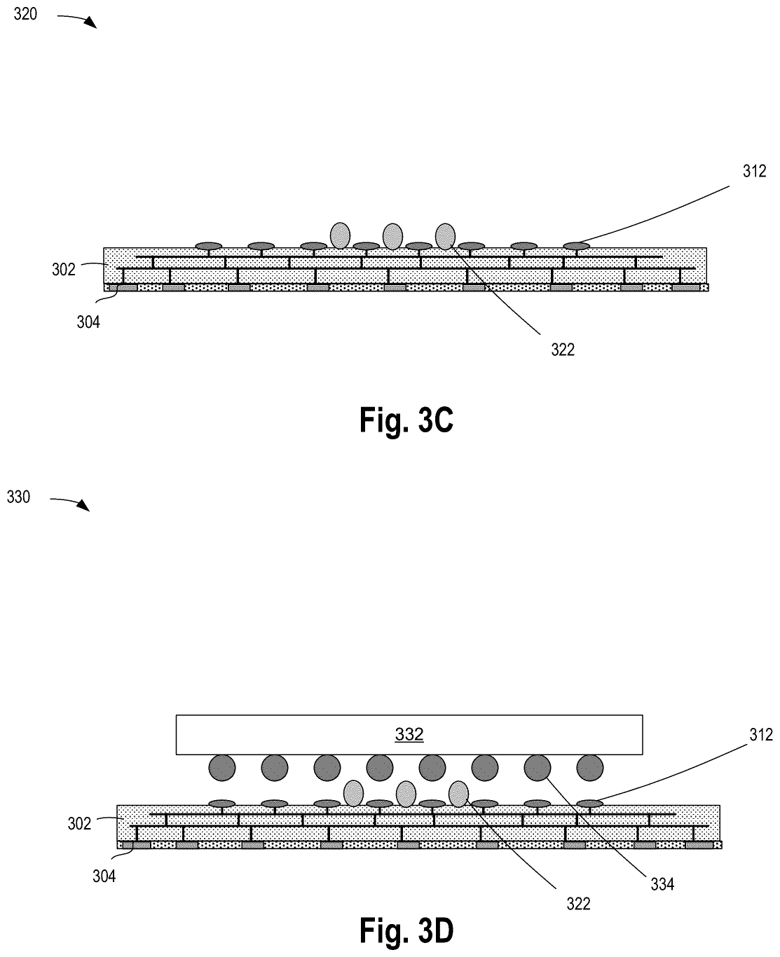

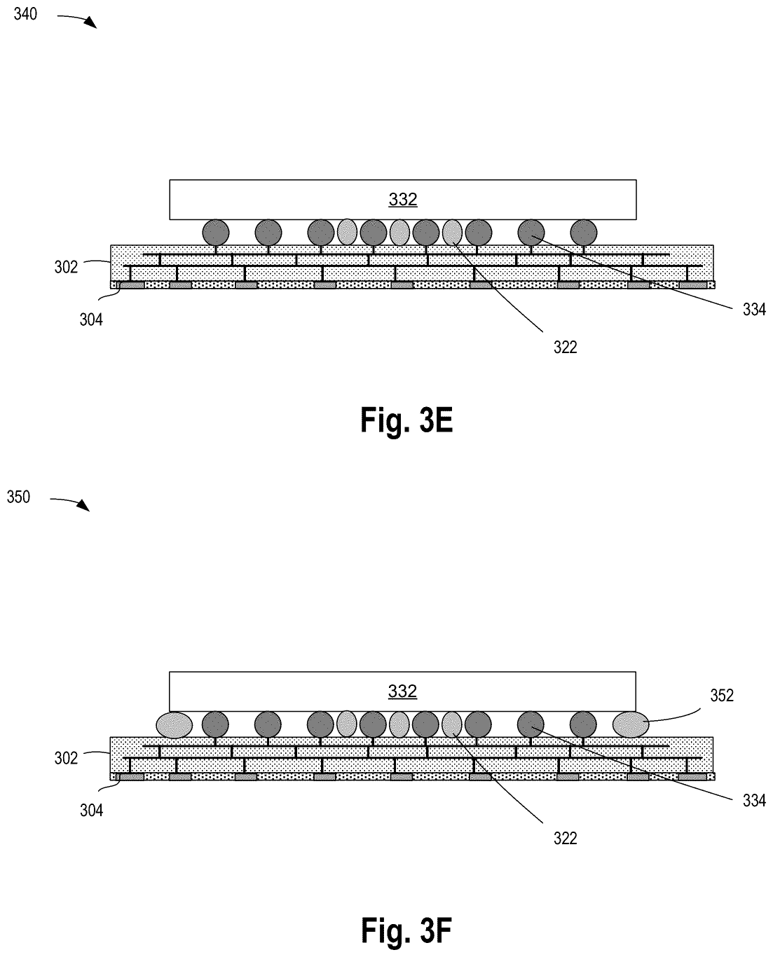

FIGS. 3A-3F illustrate cross-sectional views of example manufacturing steps of forming an example in-cavity epoxy placement for package reliability, according to some embodiments. As shown in FIG. 3A, assembly 300 includes interconnect layers 302 and package contacts 304. In some embodiments, interconnect layers 302 are iterative layers of copper and inorganic dielectric material, such as silicon oxide. In some embodiments, assembly 300 may include additional substrate layers, such as a core layer (not shown).

FIG. 3B shows assembly 310, which may include solder paste 312 over interconnect layers 302. In some embodiments, solder paste 312 may be screen printed on land or pad locations corresponding to a footprint for a BGA device.

As shown in FIG. 3C, assembly 320 may include epoxy formations 322 over interconnect layers 302. In some embodiments, epoxy formations 322 may be jetted or screen printed in cavities between instances of solder paste 312. In some embodiments, epoxy formations 322 may be placed preformed formations. In some embodiments, epoxy formations 322 consist of an epoxy resin and a hardener (usually amine) mixed together that require elevated temperature to cure.

Turning now to FIG. 3D, assembly 330 may include integrated circuit device 332 placed over interconnect layers 302 with solder contacts 334 aligned with solder paste 312. In some embodiments, integrated circuit device 332 may represent a BGA device.

FIG. 3E shows assembly 340, which may include integrated circuit device 332 bonded with interconnect layers 302. In some embodiments, a reflow process may have bonded the solder paste 312 with solder contacts 334 as well as cured the epoxy formations 322. In some embodiments, assembly 340 is heated in a reflow oven. The heat melts the solder paste, and the solder wets the PCB pads and the components, forming a strong electrical and mechanical connection. In some embodiments, the temperature of the reflow oven, the time the assembly is held at temperature, and the atmosphere in the oven all need to be carefully controlled to ensure reliable solder joints.

As shown in FIG. 3F, assembly 350 may include edge epoxy 352 between integrated circuit device 332 and interconnect layers 302. In some embodiments, edge epoxy 352 may be injected under one or more edges of integrated circuit device 332. In some embodiments, edge epoxy 352 consists of an epoxy resin and a hardener (usually amine) mixed together that require elevated temperature to cure.

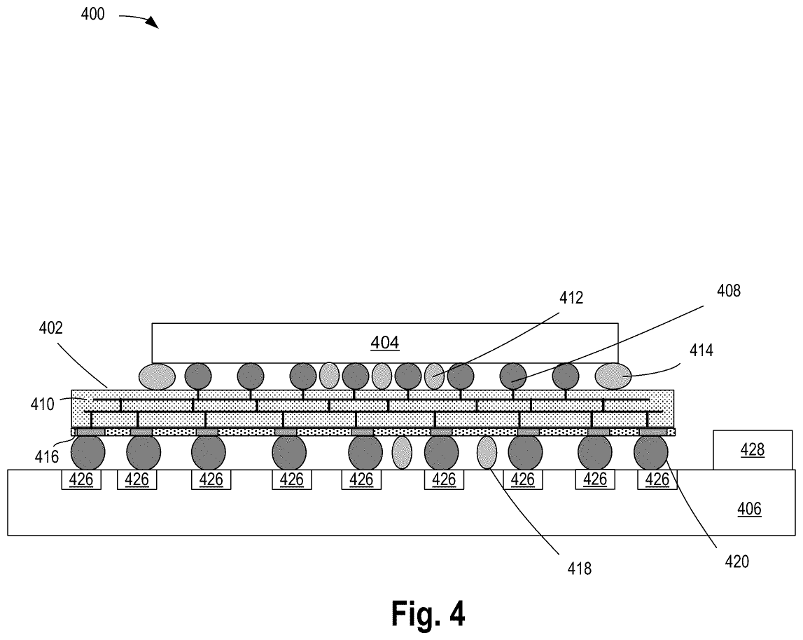

FIG. 4 illustrates a cross-sectional view of an example in-cavity epoxy placement for package reliability, according to some embodiments. As shown, assembly 400 includes device package 402, integrated circuit device 404, system board 406, solder contacts 408, interconnect layers 410, in-cavity epoxy 412, edge epoxy 414, package contacts 416, in-cavity epoxy 418, solder contacts 420, board pads 426, and board component 428.

Device package 402 may incorporate elements previously discussed in reference to prior figures. For example, elements of device package 402 may have properties discussed in reference to FIG. 1, 2, or 3A-3F. As shown, device package 402 may include integrated circuit device 404 which may be communicatively coupled with components on system board 406, such as board component 428. In some embodiments, device package 402 may include additional routing or interconnect layers, for example above or below interconnect layers 410, or other components or features, not shown herein.

In some embodiments, solder contacts 420 may be formed on a bottom surface of device package 402 thereby allowing device package 402 to be soldered to system board 406 through board pads 426. In some embodiments, solder contacts 420 may be lead or leadfree bumps or another type of connection technology. In some embodiments, in-cavity epoxy 418 may be dispensed on system board 406 before placement of device package 402. System board 406 may also incorporate board component 428, which may represent any type of active or passive system components, such as a power supply, memory devices, voltage regulators, I/O interfaces, etc.

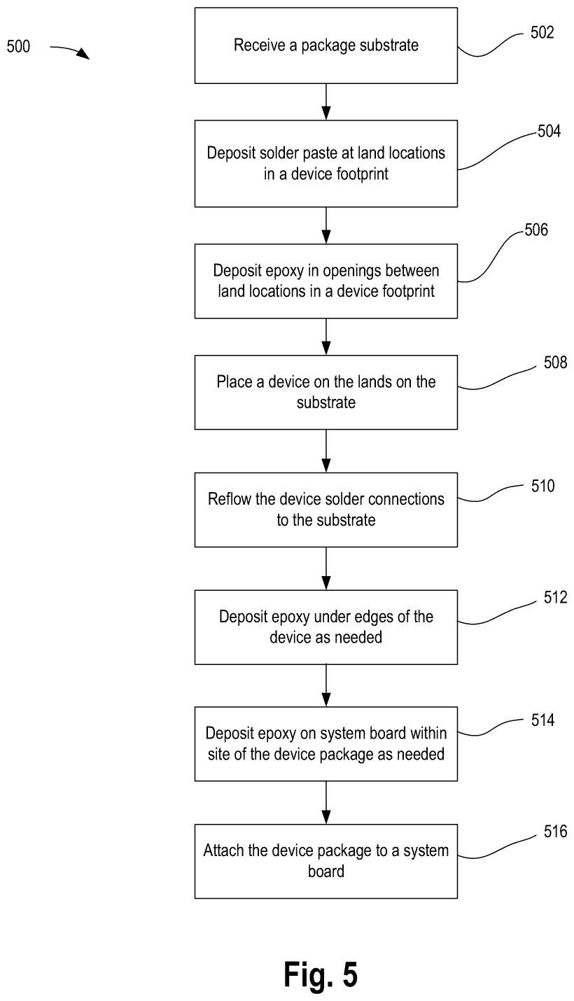

FIG. 5 illustrates a flowchart of a method of forming an example in-cavity epoxy placement for package reliability, in accordance with some embodiments. Although the blocks in the flowchart with reference to FIG. 5 are shown in a particular order, the order of the actions can be modified. Thus, the illustrated embodiments can be performed in a different order, and some actions/blocks may be performed in parallel. Some of the blocks and/or operations listed in FIG. 5 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 500 begins with receiving (502) a package substrate. In some embodiments, such as assembly 300, a package substrate may include interconnect layers 302 and package contacts 304. Next, solder paste may be deposited (504) at land locations in a device footprint. In some embodiments, such as assembly 310, solder paste 312 may be stencil printed over pads of a printed circuit board.

Then, epoxy may be deposited (506) in spaces between land locations in the device footprint. In some embodiments, such as assembly 320, epoxy 322 may be placed in one or more cavities within a BGA device footprint. Next, an integrated circuit device may be placed (508) on the lands on the substrate. In some embodiments, such as assembly 330, integrated circuit device 332 may be placed in alignment with solder paste 312.

The method continues, in some embodiments, with reflowing (510) the integrated circuit device solder contacts with the substrate. In some embodiments, such as assembly 340, solder contacts 334 may be bonded with pads on the printed circuit board. Next, epoxy may be deposited (512) under edges of the integrated circuit device. In some embodiments, such as assembly 350, edge epoxy 352 may be dispensed under integrated circuit device 332.

Next, epoxy may be deposited (514) on a system board within a device package site. In some embodiments, such as assembly 400, in-cavity epoxy 418 may be dispensed in cavities within board pads 426 on system board 406. Finally, the device package may be attached (516) to the system board. In some embodiments, solder bumps, such as solder bumps 420 on device package 402 may be soldered to board pads 426 of system board 406.

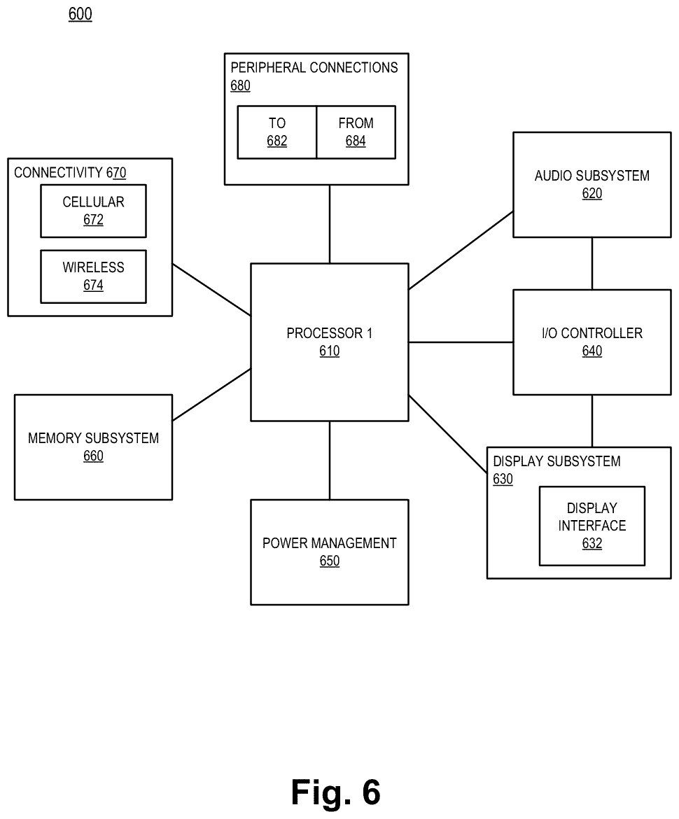

FIG. 6 illustrates a smart device or a computer system or a SoC (System-on-Chip) which includes in-cavity epoxy placement for package reliability, according to some embodiments. In some embodiments, computing device 600 represents a mobile computing device, such as a computing tablet, a mobile phone or smart-phone, a wireless-enabled e-reader, or other wireless mobile device. It will be understood that certain components are shown generally, and not all components of such a device are shown in computing device 600. In some embodiments, one or more components of computing device 600, for example processor 610 or I/O controller 640, include in-cavity epoxy placement for package reliability as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 600 includes a first processor 610. The various embodiments of the present disclosure may also comprise a network interface within 670 such as a wireless interface so that a system embodiment may be incorporated into a wireless device, for example, cell phone or personal digital assistant.

In one embodiment, processor 610 can include one or more physical devices, such as microprocessors, application processors, microcontrollers, programmable logic devices, or other processing means. The processing operations performed by processor 610 include the execution of an operating platform or operating system on which applications and/or device functions are executed. The processing operations include operations related to I/O (input/output) with a human user or with other devices, operations related to power management, and/or operations related to connecting the computing device 600 to another device. The processing operations may also include operations related to audio I/O and/or display I/O.

In one embodiment, computing device 600 includes audio subsystem 620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 600, or connected to the computing device 600. In one embodiment, a user interacts with the computing device 600 by providing audio commands that are received and processed by processor 610.

Display subsystem 630 represents hardware (e.g., display devices) and software (e.g., drivers) components that provide a visual and/or tactile display for a user to interact with the computing device 600. Display subsystem 630 includes display interface 632, which includes the particular screen or hardware device used to provide a display to a user. In one embodiment, display interface 632 includes logic separate from processor 610 to perform at least some processing related to the display. In one embodiment, display subsystem 630 includes a touch screen (or touch pad) device that provides both output and input to a user.

I/O controller 640 represents hardware devices and software components related to interaction with a user. I/O controller 640 is operable to manage hardware that is part of audio subsystem 620 and/or display subsystem 630. Additionally, I/O controller 640 illustrates a connection point for additional devices that connect to computing device 600 through which a user might interact with the system. For example, devices that can be attached to the computing device 600 might include microphone devices, speaker or stereo systems, video systems or other display devices, keyboard or keypad devices, or other I/O devices for use with specific applications such as card readers or other devices.

As mentioned above, I/O controller 640 can interact with audio subsystem 620 and/or display subsystem 630. For example, input through a microphone or other audio device can provide input or commands for one or more applications or functions of the computing device 600. Additionally, audio output can be provided instead of, or in addition to display output. In another example, if display subsystem 630 includes a touch screen, the display device also acts as an input device, which can be at least partially managed by I/O controller 640. There can also be additional buttons or switches on the computing device 600 to provide I/O functions managed by I/O controller 640.

In one embodiment, I/O controller 640 manages devices such as accelerometers, cameras, light sensors or other environmental sensors, or other hardware that can be included in the computing device 600. The input can be part of direct user interaction, as well as providing environmental input to the system to influence its operations (such as filtering for noise, adjusting displays for brightness detection, applying a flash for a camera, or other features).

In one embodiment, computing device 600 includes power management 650 that manages battery power usage, charging of the battery, and features related to power saving operation. Memory subsystem 660 includes memory devices for storing information in computing device 600. Memory can include nonvolatile (state does not change if power to the memory device is interrupted) and/or volatile (state is indeterminate if power to the memory device is interrupted) memory devices. Memory subsystem 660 can store application data, user data, music, photos, documents, or other data, as well as system data (whether long-term or temporary) related to the execution of the applications and functions of the computing device 600.

Elements of embodiments are also provided as a machine-readable medium (e.g., memory 660) for storing the computer-executable instructions. The machine-readable medium (e.g., memory 660) may include, but is not limited to, flash memory, optical disks, CD-ROMs, DVD ROMs, RAMS, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 670 includes hardware devices (e.g., wireless and/or wired connectors and communication hardware) and software components (e.g., drivers, protocol stacks) to enable the computing device 600 to communicate with external devices. The computing device 600 could be separate devices, such as other computing devices, wireless access points or base stations, as well as peripherals such as headsets, printers, or other devices.

Connectivity 670 can include multiple different types of connectivity. To generalize, the computing device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 680 include hardware interfaces and connectors, as well as software components (e.g., drivers, protocol stacks) to make peripheral connections. It will be understood that the computing device 600 could both be a peripheral device (“to” 682) to other computing devices, as well as have peripheral devices (“from” 684) connected to it. The computing device 600 commonly has a “docking” connector to connect to other computing devices for purposes such as managing (e.g., downloading and/or uploading, changing, synchronizing) content on computing device 600. Additionally, a docking connector can allow computing device 600 to connect to certain peripherals that allow the computing device 600 to control content output, for example, to audiovisual or other systems.

In addition to a proprietary docking connector or other proprietary connection hardware, the computing device 600 can make peripheral connections 680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a device surface, wherein the device surface comprises an array of solder contacts;
a substrate surface, wherein the substrate surface comprises an array of pads, the array of solder contacts coupled with the array of pads; and
a formation of epoxy coupled with the device surface and the substrate surface, wherein the formation of epoxy is entirely within an area of the array of solder contacts.

2. The apparatus of claim 1, further comprising a second formation of epoxy coupled with the device surface and the substrate surface, wherein the second formation of epoxy is entirely outside an area of the array of solder contacts.

3. The apparatus of claim 1, wherein the substrate surface comprises a printed circuit board surface.

4. The apparatus of claim 1, wherein the device surface comprises an integrated circuit device surface.

5. The apparatus of claim 1, further comprising the formation of epoxy comprising 30-85 percent by volume of fillers.

6. The apparatus of claim 1, wherein the formation of epoxy comprises multiple discrete deposits of epoxy.

7. The apparatus of claim 1, wherein the formation of epoxy is within a cavity formed by an absence of solder contacts within the array of solder contacts.

8. A system comprising:
a host board;
an integrated circuit device package, the integrated circuit device package comprising:
a device surface, wherein the device surface comprises an array of solder contacts;
a substrate surface, wherein the substrate surface comprises an array of pads, the array of solder contacts coupled with the array of pads; and
a formation of epoxy coupled with the device surface and the substrate surface, wherein the formation of epoxy is entirely within an area of the array of solder contacts; and
a power supply to provide power to the integrated circuit device package through the host board.

9. The system of claim 8, further comprising a second formation of epoxy coupled with the device surface and the substrate surface, wherein the second formation of epoxy is entirely outside an area of the array of solder contacts.

10. The system of claim 8, wherein the substrate surface comprises a printed circuit board surface.

11. The system of claim 8, wherein the device surface comprises an integrated circuit device surface.

12. The system of claim 8, further comprising the formation of epoxy comprising 30-85 percent by volume of fillers.

13. The system of claim 8, wherein the formation of epoxy comprises multiple discrete deposits of epoxy.

14. The system of claim 8, wherein the formation of epoxy is within a cavity formed by an absence of solder contacts within the array of solder contacts.

15. A method comprising:
printing solder paste on pads of a substrate surface;
placing epoxy within a footprint of the solder paste;
placing a device with solder contacts in alignment with the pads; and
bonding the solder contacts with the pads.

16. The method of claim 15, further comprising placing epoxy between the device and the substrate surface outside the footprint of the solder paste.

17. The method of claim 15, wherein placing epoxy comprises screen printing epoxy.

18. The method of claim 15, wherein placing epoxy comprises jetting.

19. The method of claim 15, wherein placing epoxy comprises placing a preformed epoxy.

20. The method of claim 15, wherein bonding the solder contacts with the pads comprising reflowing the solder contacts.
